(19) United States
(12) Patent Application Publication
(10) Pub. No.: US 2021/0226417 A1
(43) Pub. Date: Jul. 22, 2021

(54) AMBIENT LIGHT REJECTING SCREEN

(71) Applicants: BENQ CORPORATION, Taipei (TW); BenQ Intelligent Technology Shanghai Co., Ltd, Shanghai (CN)

(72) Inventors: Yuan-Chen LIAO, Taipei City (TW); Chen-Cheng HUANG, Taoyuan City (TW); Chin-Fu CHIANG, New Taipei City (TW)

(73) Assignees: BENQ CORPORATION, Taipei (TW); BenQ Intelligent Technology Shanghai Co., Ltd, Shanghai (CN)

(21) Appl. No.: 17/151,715

(22) Filed: Jan. 19, 2021

(30) Foreign Application Priority Data
Jan. 19, 2020 (CN) 202010061818.X

(51) Int. Cl. H01S 5/10; G02B 5/28

(52) U.S. Cl. CPC H01S 5/1042; G02B 5/286

(57) ABSTRACT

An ambient light rejecting screen used in a laser light source projector, which generates a light with a first wavelength and a light with a second wavelength, is provided. The screen includes a base, a light absorbing layer, a first filter layer and a second filter layer. The light absorbing layer is disposed on the base. The first filter layer is disposed on the light absorbing layer. The crystallization characteristic of the first filter layer corresponds to the light with the first wavelength and generates a reflective light with the first wavelength, and allows the light with remaining wavelengths to pass through. The second filter layer is disposed on the light absorbing layer. The crystallization characteristic of the second filter layer corresponds to the light with the second wavelength used to generate the reflective light with the second wavelength and allows the light with remaining wavelengths to pass through.

This application claims the benefit of People's Republic of China application Serial No. 202010061818.X, filed Jan. 19, 2020, the subject matter of which is incorporated herein by reference.

### BACKGROUND OF THE INVENTION

### Field of the Invention

The invention relates in general to a projection screen, and more particularly to an ambient light rejecting screen.

### Description of the Related Art

According to the prior art, after the projector projects a light to a screen (or curtain), an image is formed on the screen and then is reflected to the viewer's eyes. If an ambient stray light, such as the sunlight or the light of a lighting device, also illuminates the screen, the viewer will view the ambient stray light reflected from the screen in addition to the image, such that the contrast or color saturation of the image projected on the screen will deteriorate.

### SUMMARY OF THE INVENTION

The invention is directed to an ambient light rejecting screen which reduces the interference of the ambient light on the image projected on the screen.

According to one embodiment the present invention, an ambient light rejecting screen used in a laser light source projector is provided. The laser light source projector generates a light with a first wavelength and a light with a second wavelength. The screen includes a base, a light absorbing layer, a first filter layer and a second filter layer. The light absorbing layer is disposed on the base. The first filter layer is disposed on the light absorbing layer. The crystallization characteristic of the first filter layer corresponds to the light with the first wavelength and generates a reflective light with the first wavelength, and allows the light with remaining wavelengths to pass through the first filter layer. The second filter layer is disposed on the light absorbing layer. The crystallization characteristic of the second filter layer corresponds to the light with the second wavelength and generates a reflective light with the second wavelength and allows the light with remaining wavelengths to pass through the second filter layer.

In comparison to the existing technologies, the application of the ambient light rejecting screen of the present invention is not limited to the laser light source projector, and can also be used in the projector with a light source of three primary colors (red, green and blue), a light source of white light LED or a light source of a continuous spectrum or a non-continuous spectrum as long as the screen can reflect a specific light in a narrow-band spectrum (e.g., including the spectrum of the red light, the blue light and the green light of the image outputted by the projector). Thus, the image brightness will not be affected by the stray light. Since the ambient light rejecting screen of the present invention can inhibit the stray light of a continuous spectrum, the viewer will not view the ambient stray light reflected from the screen, and the contrast or color saturation of the image projected on the screen will not deteriorate and achieve the effect of ambient light rejection.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of an ambient light rejecting screen according to the present invention an embodiment.

### DETAILED DESCRIPTION OF THE INVENTION

For the objects, structures and features of the present invention to be better understood, a number of embodiment are disclosed below.

Detailed descriptions of the invention are disclosed below with a number of embodiments. However, the disclosed embodiments are for explanatory and exemplary purposes only, not for limiting the scope of protection of the invention. Similar/identical designations are used to indicate similar/identical elements.

According to an embodiment of the present invention, an ambient light rejecting screen is provided. The ambient light rejecting screen of the present invention avoids the image being interfered with by the stray light of a continuous spectrum (such as the sunlight, and the light emitted by a fluorescent tube or a mercury lamp). Meanwhile, the ambient light rejecting screen of the present invention is provided with spectral selectivity and reflects only a specific light in a narrow-band spectrum (e.g., including the spectrum of the red light, the blue light and the green light of the image outputted by the projector). Thus, the image brightness will not be affected. Furthermore, the ambient light rejecting screen of the present invention can inhibit the stray light of a continuous spectrum and achieve the effect of ambient light rejection.

According to an embodiment of the present invention, the ambient light rejecting screen filters the light according to the crystallization characteristic and the grain boundary characteristic of the material and reflects only the light with a specific wavelength but allows the light with remaining wavelengths to pass through the filter layer and reach the light absorbing layer. That is, the filter layer is highly reflective towards the image projected on the screen and the three primary colors (red, green and blue) in the ambient light, such that the light of other colors (other than the three primary colors) can pass through the filter layer to be absorbed by the light absorbing layer, and the interference caused by the ambient light can be inhibited.

According to an embodiment of the present invention, the filter layer can become highly reflective towards the light with a specific spectrum by adjusting the grain size of the material or adjusting the arrangement of crystal structures (the crystal structures of the artificial or natural crystals, such as ruby, emerald and sapphire). In terms of the grain size, since the nano-level quantum dot particles, glass-based crystal particles or emulsion colloid particles are highly reflective towards the light of a specific spectrum, the screen of the present embodiment, with the adjustment of the grain size of glass crystal particles or emulsion colloid particles of the filter layer, can filter the light and inhibit the interference of the ambient light.

In terms of the quantum dots particles, the emulsion colloid particles or the glass-based crystal particles, different color lights in the range of spectrums from 400 nm to 700 nm can be reflected when the grain size is changed. For example, when the grain size is large, the red light can be reflected; when the grain size is medium, the green light can be reflected; when the grain size is small, the blue light can be reflected, and the rest can be obtained by the same analogy. The grain size of emulsion colloid particles or quantum dots is in a range of 2 nm-10 nm, but the present invention is not limited thereto.

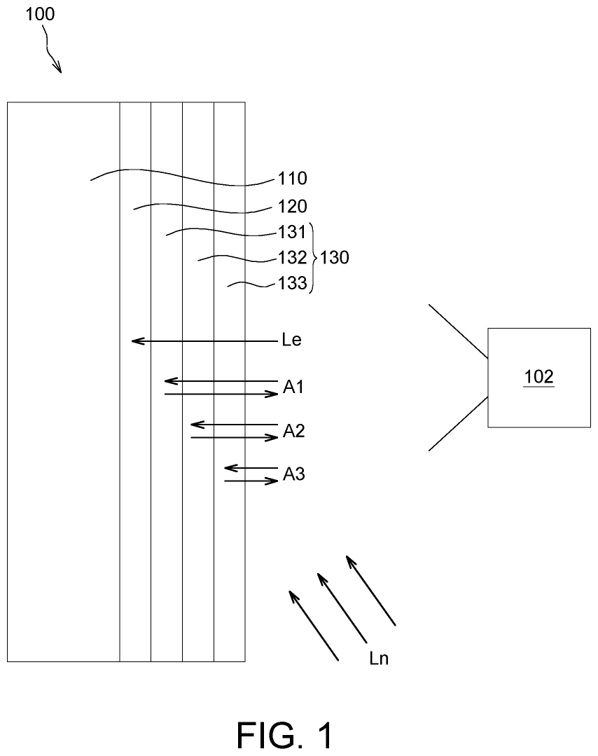

Referring to FIG. 1, a schematic diagram of an ambient light Ln rejecting screen 100 according to an embodiment of the present invention is shown. The ambient light rejecting screen 100 is used in a laser light source projector 102, which generates a light with a first wavelength A1 and a light with a second wavelength A2. The screen 100 includes a base 110, a light absorbing layer 120, a first filter layer 131 and a second filter layer 132. The light absorbing layer 120 is disposed on the base 110. The first filter layer 131 is disposed on the light absorbing layer 120. That is, the light absorbing layer 120 is located between the base 110 and the first filter layer 131. The crystallization characteristic of the first filter layer 131 corresponds to the light with the first wavelength A1 and generates a reflective light with the first wavelength A1 but allows the light Le with remaining wavelengths except the first wavelength A1 to pass through the first filter layer 131. The second filter layer 132 is disposed on the light absorbing layer 120. That is, the light absorbing layer 120 is located between the base 110 and the second filter layer 132. The crystallization characteristic of the second filter layer 132 corresponds to the light with the second wavelength A2 and generates a reflective light with the second wavelength A2 but allows the light Le with remaining wavelengths except the second wavelength A2 to pass through the second filter layer 132. The first filter layer 131 and the second filter layer 132 stack on each other. In another embodiment, the laser light source projector 102 further generates a light with a third wavelength A3, and the screen 100 further includes a third filter layer 133 disposed on the light absorbing layer 120. The first filter layer 131, the second filter layer 132 and the third filter layer 133 stack on each other. The crystallization characteristic of the third filter layer 133 corresponds to the light with the third wavelength A3 and generates a reflective light with the third wavelength A3 but allows the light Le with remaining wavelengths except the third wavelength A3 to pass through the third filter layer 133. The first filter layer 131, the second filter layer 132 and the third filter layer 133 stack on each other but the stacking order of the three filter layers 130 is not restricted.

The three filter layers 130 (including a first filter layer 131, a second filter layer 132, and a third filter layer 133) are not limited to three layered, and can also be single-layered or double-layered. Therefore, the ambient light rejecting screen 100 of the present embodiment can be highly reflective only towards one color light, two color lights or multiple color lights with specific wavelengths but allow the light Le with remaining wavelengths to be absorbed by the light absorbing layer 120, such that the interference of the ambient light Ln can be inhibited.

In an embodiment, the filter layers 130 include a red light filter layer, a blue light filter layer and a green light filter layer used to reflect the lights of three primary colors (red, green and blue), respectively, such that the viewer can view the lights of three primary colors (red, green and blue) of the image projected on the screen 100. Besides, the light absorbing layer 120 is used to absorb the lights other than the three primary colors, such that the interference of color and/or brightness of the image caused by the light Le with remaining wavelengths can be inhibited. Thus, the ambient light rejecting screen 100 of the present embodiment can avoid the problems that the contrast or color saturation of the image projected on the screen 100 deteriorates.

In an embodiment, the filter layers 130 have identical thickness, and each of the filter layers 130 is single-layered, such that the thickness of film can be reduced (up to the nano-level thickness). That is, each of the filter layers 130 can be formed of a single film of reflective material instead of multiple interfering films, such that the thickness of each of the filter layers 130 can be uniform and the problems that stacked layers of multiple interfering films have large residual stress and have difficulty with accurate control of thickness can be avoided.

In an embodiment, the filter layers 130 are respectively formed by way of printing or transferring. In another embodiment, the filter layers 130 are respectively formed by way of spraying or coating. That is, each of the filter layers 130 can be formed on the base 110 (curtain material) by way of printing, transferring, spraying or coating. The filter layers 130 can be manufactured at a lower cost and can facilitate the screen 100 for rolling and unrolling. Furthermore, the film thickness of the filter layers 130 is reduced (up to the nano-level thickness), no residual stress is generated between the layers, and the screen 100 will not be too thick to be rolled or unrolled.

In an embodiment, the filter layers 130 are formed by the crystallization of quantum dot particles. The quantum dots particles include at least one of silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots and indium arsenide quantum dots. The filter layers include a red light filter layer, a blue light filter layer and a green light filter layer. The filter layers 130 filter the light by changing the grain size of the quantum dots. That is, when the grain size of the quantum dots is large (such as 10 nm), the light with the first wavelength A1 (such as the red light) can be reflected; when the grain size of the quantum dots is medium (such as 5 nm), the light with the second wavelength A2 (such as the green light) can be reflected; when the grain size of the quantum dots is small (such as 2 nm), the light with the third wavelength A3 (such as the blue light) can be reflected, and the rest can be obtained by the same analogy. Thus, if the quantum dots of the filter layers 130 formed on the base 110 of curtain material have different grain sizes, the filter layers 130 can reflect one color light, two color lights or multiple color lights with specific wavelength but allows the light Le with remaining wavelengths to be absorbed by the light absorbing layer 120, such that the interference of the ambient light Ln can be inhibited.

In another embodiment, the filter layers 130 are formed by the crystallization of nano-level glass or emulsion colloid particles. The filter layers 130 filter the light by changing the grain size of the glass or emulsion colloid particles. The colloidal particles, for example, are 2-hydroxyethyl methacrylate (HEMA) polymer. The nano-level particles of glass or emulsion colloid crystalized on the silicone surface can reflect the lights of three primary colors (red, green and blue), and different grain sizes (particle sizes) reflect the light of different colors. That is, when the grain size of the colloid particles is large (such as 10 nm), the light with the first wavelength A1 (such as the red light) can be reflected; when the grain size of the colloid particles is medium (such as 5 nm), the light with the second wavelength A2 (such as the green light) can be reflected; when the grain size of the colloid particles is small (such as 2 nm), the light with the third wavelength A3 (such as the blue light) can be reflected, and the rest can be obtained by the same analogy. Thus, if the filter layers 130 formed on the base 110 of curtain material have micro dotted structures of different grain sizes, the filter layers 130 can reflect one color light, two color lights or multiple color lights with specific wavelength but allow the light Le with remaining wavelengths to be absorbed by the light absorbing layer 120, such that the interference of the ambient light Ln can be inhibited.

In another embodiment, the filter layers 130 can be formed of unit cells arranged according to the crystal structure of ruby, emerald and sapphire. Each of ruby, emerald and sapphire has a respective grain boundary characteristic of unit cells and has a respective reflectivity towards different wavelengths of the light. That is, the unit cells of ruby can reflect the light with the first wavelength A1 (such as the red light); the unit cells of emerald can reflect the light with the second wavelength A2 (such as the green light); the unit cells of sapphire can reflect the light with the third wavelength A3 (such as the blue light), and the rest can be obtained by the same analogy. Thus, if the filter layers 130 formed on the base 110 of curtain material have respective grain boundary characteristics of unit cells of ruby, emerald and sapphire, the filter layers 130 can reflect one color light, two color lights or multiple color lights with specific wavelength but allows the light Le with remaining wavelengths to be absorbed by the light absorbing layer 120, such that the interference of the ambient light Ln can be inhibited.

The application of the ambient light rejecting screen of the present invention is not limited to the laser light source projector, and can also be used in the projector with a light source of three primary colors (red, green and blue), a light source of white light LED or a light source of a continuous spectrum or a non-continuous spectrum as long as the screen reflects only the light of a narrow-band spectrum (including the spectrum of the red light, the blue light and the green light of the image outputted by the projector). Thus, the image brightness will not be affected by the stray light. Since the ambient light rejecting screen of the present invention can inhibit the stray light of a continuous spectrum, the viewer will not view the ambient stray light reflected from the screen (the ambient stray light is absorbed by the light absorbing layer), and the contrast or color saturation of the image projected on the screen will not deteriorate and achieve the effect of ambient light rejection.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An ambient light rejecting screen used in a laser light source projector, wherein the laser light source projector generates a light with a first wavelength and a light with a second wavelength, and the screen comprises:
a base;
a light absorbing layer disposed on the base;
a first filter layer disposed on the light absorbing layer, wherein a crystallization characteristic of the first filter layer corresponds to the light with the first wavelength and generates a reflective light with the first wavelength and allows a light with remaining wavelengths to pass through the first filter layer, and the light absorbing layer is located between the base and the first filter layer; and
a second filter layer disposed on the light absorbing layer, wherein a crystallization characteristic of the second filter layer corresponds to the light with the second wavelength and generates a reflective light with the second wavelength and allows the light with remaining wavelengths to pass through the second filter layer, and the light absorbing layer is located between the base and the second filter layer;
wherein, the first filter layer and the second filter layer stack on each other.

2. The screen according to claim 1, wherein the laser light source projector generates a light with a third wavelength, and the screen further comprises:
a third filter layer disposed on the light absorbing layer, wherein a crystallization characteristic of the third filter layer corresponds to the light with the third wavelength and generates a reflective light with the third wavelength and allows the light with remaining wavelengths to pass through the third filter layer, and the first filter layer, the second filter layer and the third filter layer stack on each other.

3. The screen according to claim 2, wherein the filter layers comprise a red light filter layer, a blue light filter layer and a green light filter layer, respectively used to reflect three primary color lights of red, green and blue, and the light absorbing layer is used to absorb color lights other than the three primary colors.

4. The screen according to claim 2, wherein the filter layers have identical thickness.

5. The screen according to claim 2, wherein the filter layers respectively are single-film layers.

6. The screen according to claim 2, wherein the filter layers are respectively formed by way of printing, transferring, spraying or coating.

7. The screen according to claim 2, wherein the filter layers are formed by crystallization of quantum dot particles.

8. The screen according to claim 7, wherein the quantum dots particles comprise at least one of silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots and Indium arsenide quantum dots.

9. The screen according to claim 7, wherein the filter layers comprise a red light filter layer, a blue light filter layer and a green light filter layer, the filter layers filter lights by changing grain size of the quantum dots, and the grain size of the quantum dots of the filter layers is in a range of 2-10 nm.

10. The screen according to claim 2, wherein the filter layers are formed by crystallization of nano-level glass or emulsion colloid particles, and the filter layers filter lights by changing grain size of nano-level glass or emulsion colloid particles.

11. The screen according to claim 10, wherein the colloid particles are 2-hydroxyethyl methacrylate polymers.

12. The screen according to claim 2, wherein the filter layers are formed of unit cells arranged according to crystal structures of ruby, emerald and sapphire.

13. The screen according to claim 12, wherein the crystal structures are artificial crystals or natural crystals exist in nature.

14. The screen according to claim 2, wherein the filter layers are used to reflect color lights in a range of spectrum of 400 nm-700 nm.

15. The screen according to claim 2, wherein the screen reflects the light according to grain size of colloid of the filter layers, the colloid with large grain size reflects red light, the colloid with medium grain size reflects green light, and the colloid with small grain size reflects blue light.

16. The screen according to claim 2, wherein the screen reflects the light according to grain size of quantum dots of the filter layers, the quantum dots with large grain size reflects red light, the quantum dots with medium grain size reflects green light, and the quantum dots with small grain size reflects blue light.

17. The screen according to claim 1, wherein the light absorbing layer absorbs color lights other than the light with the first wavelength and the light with the second wavelength.

18. The screen according to claim 2, wherein the light absorbing layer absorbs color lights other than the light with the first wavelength, the light with the second wavelength and the light with the third wavelength.

19. The screen according to claim 1, wherein the light absorbing layer absorbs an ambient stray light of a continuous spectrum.

20. The screen according to claim 1, wherein the screen is used to avoid an interference of an ambient stray light of a continuous spectrum.
